(19) United States
(12) Patent Application Publication
(10) Pub. No.: US 2008/0030815 A1
(43) Pub. Date: Feb. 7, 2008

(54) Display for a digital photo album

(75) Inventors: Bruce Teicher, Chagrin Falls, OH (US); Crystal Teicher, Chagrin Falls, OH (US)

Correspondence Address: FAY SHARPE LLP, 1100 SUPERIOR AVENUE, SEVENTH FLOOR, CLEVELAND, OH, 44114, US

(73) Assignee: Photoco, Inc.

(21) Appl. No.: 11/498,545

(22) Filed: Aug. 3, 2006

(51) Int. Cl. G03F 3/10

(52) U.S. Cl. 358/527

(57) ABSTRACT

A display for an associated digital photo album includes a frame member including a front face and a rear face, a socket located in the frame member for removably receiving the associated digital photo album, and a retaining lip disposed about the socket of the frame member. The retaining lip restricts the movement of the associated digital photo album beyond the front face of the frame member. The display further includes a cover moveably mounted to the rear face of the frame member for retaining the associated digital photo album in the frame member. The frame member and the cover substantially enclose the associated digital photo album, except for a screen thereof, when the cover is in the closed position.

### BACKGROUND

The present invention relates to the field of photo album display devices. It finds particular application in conjunction with photo displays adapted to accommodate digital photo display devices.

Displays for digital photo albums are known for providing an aesthetic means of displaying digital images or photos. Generally, they provide a convenient hands-free method of viewing photos in a typical home such as on a mantle, coffee table, end table or wall. However, the prior art digital photo album displays suffer from a number of disadvantages.

One disadvantage involves the fact that some prior art displays do not substantially enclose the digital photo album, leaving it relatively unprotected from accidental bumps or drops. The electrical components within a digital photo album are sensitive to shock and repeated exposure to vibration or shock can significantly reduce the life span of the digital photo album. For this reason, a need exists to provide a display with a means of damping shock from an occasional bump or fall.

Another disadvantage with some prior art displays is that they do not substantially conceal the user controls of the display. Not only are exposed user controls less aesthetic but they are also easily tampered with. For example, young children often find the buttons of small portable electronics very enticing. Repeated tampering with such electronic equipment is not only annoying to the primary or intended user but will also shorten the life span of the product. For this reason, a need exists to provide a display having a means of concealing the user controls of a digital photo album.

Yet another disadvantage with prior art displays is that, even to the casual observer, it is readily apparent that the display contains some type of digital electronics. The small overall size of the digital photo album and its relatively high value make it an attractive prospect for would-be thieves. For this reason, prior art displays do not provide a generally stealthy appearance for the purposes of theft prevention.

Accordingly, it is desirable to develop a new and improved digital photo album display which would overcome the foregoing deficiencies and others while meeting the above stated needs and providing better and more advantageous results.

### SUMMARY OF THE INVENTION

According to one aspect of the present invention, a display for an associated digital photo album includes a frame member including a front face and a rear face, a socket located in the frame member for removably receiving the associated digital photo album, and a retaining lip disposed about the socket of the frame member. The retaining lip restricts the movement of the associated digital photo album beyond the front face of the frame member. The display further includes a cover moveably mounted to the rear face of the frame member for retaining the associated digital photo album in the frame member. The frame member and the cover substantially enclose the associated digital photo album, except for a screen thereof, when the cover is in the closed position.

According to another aspect of the present invention, display for an associated digital photo album includes a plurality of frame elements arranged to form a generally rectangular assembly, the assembly including a front face and a rear face, a socket portion defined by the plurality of frame elements for selectively receiving the associated digital photo album. The socket portion initiating at the rear face of the assembly and extending towards the front face thereof. The display further includes a viewing window defined in the front face of the assembly, the window being in communication with the socket portion. Furthermore the display includes a cover secured to the rear face of the assembly for retaining the associated digital photo album, the cover having an open position and a closed position and a support leg secured to the cover, the support leg including a closed position and an open position. The plurality of frame elements, the cover, and the support leg support the associated digital photo album on an associated horizontal surface when the cover member is in the closed position and the support leg is in the open position.

According to yet another aspect of the present invention, a display for selectively supporting an associated digital photo album includes a frame member including a front face and a rear face, a socket defined in the frame member and extending therethrough from said rear face to said front face thereof, and a lip defined on said frame member front face so that a front opening of said frame member has a smaller area than a rear opening of said frame member. The display further includes a cover moveably mounted to said frame member rear face and selectively closing said rear opening thereof. Wherein, the frame member and the cover cooperate to substantially enclose the associated digital photo album, except for a screen thereof.

Other benefits and advantages of the invention will become apparent to those of average skill in the art upon a reading of the following detailed specification.

### BRIEF DESCRIPTION OF THE DRAWINGS

The invention may take form in certain structures and components, several embodiments of which will be described in detail in this specification and illustrated in the accompanying drawings. In the drawings:

FIG. 1 is a front perspective view of a first embodiment of a display for an associated digital photo album, according to the present invention, illustrating the digital photo album inserted into the display.

FIG. 2 is a rear oblique view of the display of FIG. 1 illustrating a cover in an open position and a socket for receiving the digital photo album.

FIG. 3 is a rear perspective view of the display of FIG. 1 illustrating the cover member in a closed position, a clasp in a locked position, a support leg in an open position, and an electrical cable in a cable channel.

FIG. 4 is a rear perspective view of a second embodiment of a display for an associated digital photo album, according to the present invention, illustrating a socket and a single clasp for receiving a compact digital photo album.

FIG. 5 is a front perspective view of the display of FIG. 4 illustrating the compact digital photo album inserted into the display.

FIG. 6 is a perspective view of a user holding the compact digital photo album of FIG. 5.

### DETAILED DESCRIPTION

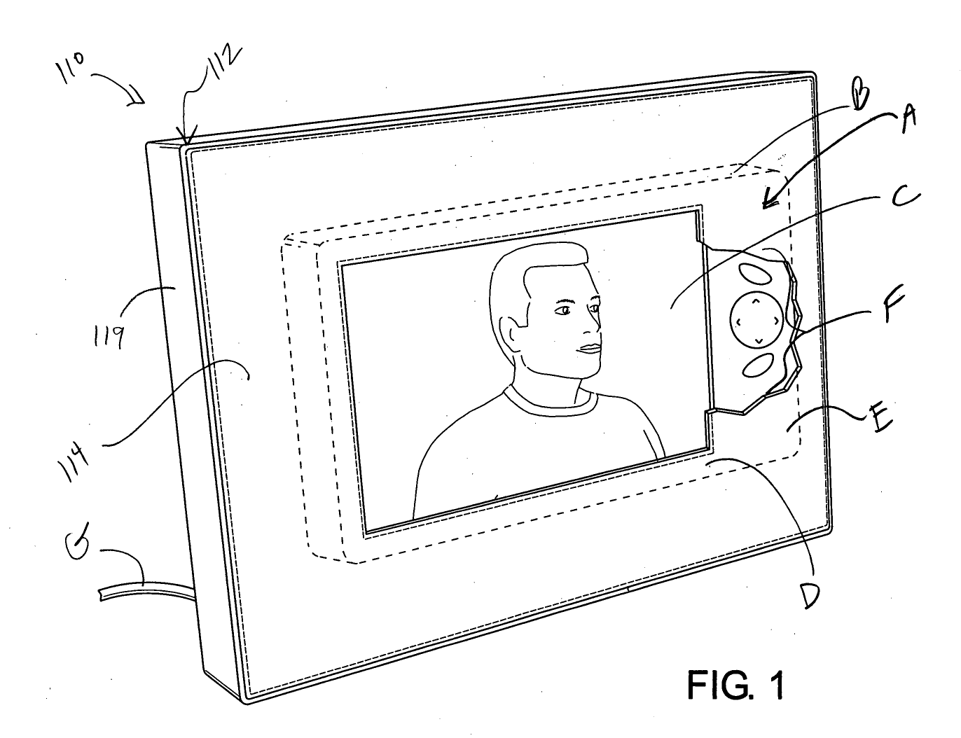

With reference to FIGS. 1-3, a digital photo album display 110 is configured to receive a portable handheld digital photo album A. The display 110 generally includes a frame 112 having a front face 114 and a rear face 116. A socket 118 is defined in the frame 112 between the front face 114 and the rear face 116 and is sized to accommodate the overall height, width and depth dimensions of the digital photo album A.

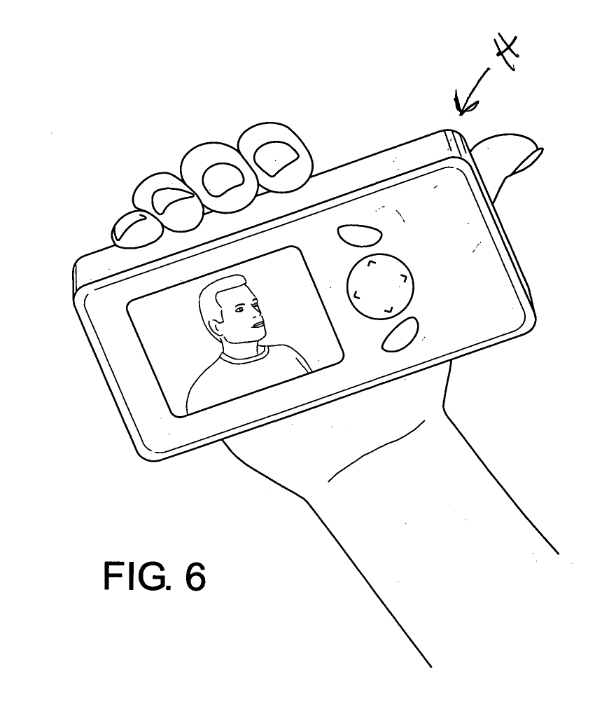

The photo album A includes a housing B and a screen C disposed along a front wall D. The photo album A also includes a user interface portion E having a plurality of user controls F. The plurality of user controls F may include a four-way menu button for setting a variety of display modes, adjusting brightness, and or selecting a source/input. In addition, forward/reverse directional control buttons may also be provided. The digital photo album A is designed to be a handheld unit which can be easily transported for the specific purpose of viewing or sharing digital images with others. With reference to FIG. 6, a more compact digital photo album H is shown that is substantially identical in function to the digital photo album A of FIG. 1. As illustrated, the primary difference between the digital photo album A (FIG. 1) and the compact digital photo album H (FIG. 6) is that the digital photo album A (FIG. 1) includes a larger screen C having a greater viewing area.

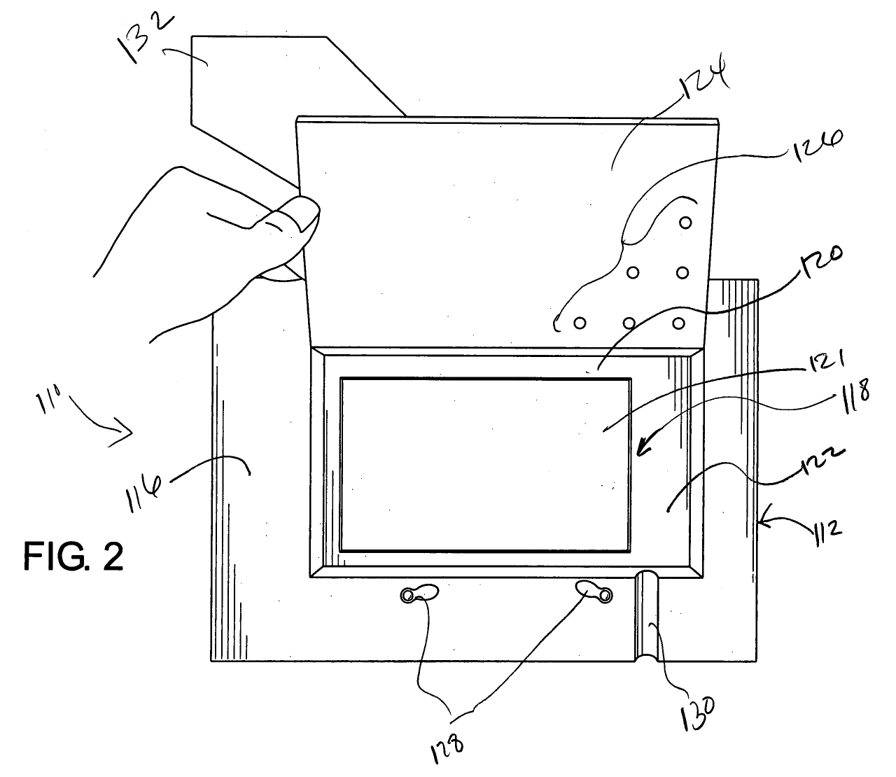

With reference once again to FIGS. 1-2, the photo album A may be inserted into the display 110 from the rear face of the frame 112. In an alternate embodiment, the frame 112 could include an opening (not shown) along the peripheral edge 119 thereof such that the digital photo album A could be slid into the frame 112 sideways rather than from the rear. The frame 112 further includes a lip 120 which extends about the circumference of the socket 118 on the front face 114 of the frame 112. A viewing window 121 is defined within the perimeter of the lip 120 and is coincident with a plane of the lip 120. When the photo album A is inserted into the socket 118 the screen C is in general alignment with the viewing window 121. The lip 120 also prevents the digital photo album A from sliding or falling out of the frame 112 past the front face 114 thereof. Also, as shown in FIG. 2, an enlarged portion 122 of the lip 120 serves the purpose of concealing the user interface portion E of the digital photo album A and thus prevents access to the plurality of user controls F.

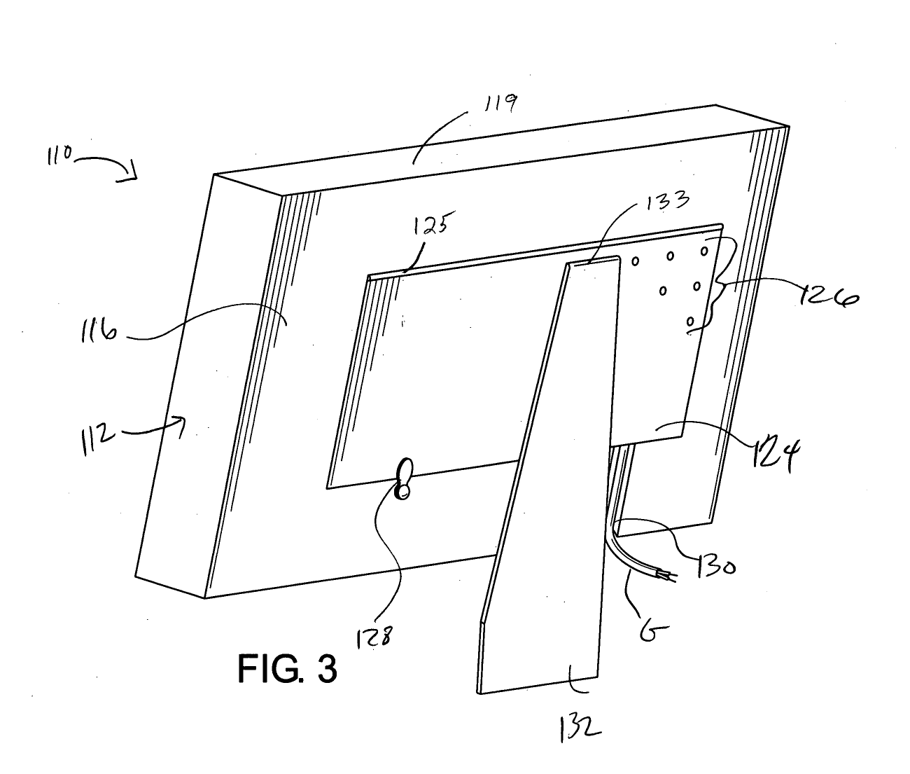

With continued reference to FIG. 2, the display 110 also includes a cover 124 which may be hingedly attached to the frame 112. For this purpose, a hinge 125 can be employed. The cover 124 can be placed in an open position and a closed position. FIG. 2 clearly illustrates the open position while FIG. 3 illustrates the cover 124 in the closed position. When the cover 124 is in the closed position, one or more clasps 128 may be rotated in order to lock the cover 124 in the closed position. Two such clasps are illustrated in this embodiment. With the cover 124 in the closed position, the display 110 will substantially enclose all the surfaces of the photo album A, with exception of the screen C. Thus, the material of the display forms a protective impact barrier between the photo album A and a potential impact surface, such as a table top or floor. Foam padding and or a leather/vinyl clad exterior may be added to the display 110 to increase the energy absorbing characteristics of the display 110 and to decrease the level of shock (or Gs) transmitted to the photo album A during an impact. Also, it should be noted that the cover 124 could be attached to the frame 112 in various ways. For instance, the cover could be hingedly attached, as shown in the FIGS. 1-3, or the cover could be slidably or snappingly engaged with the frame. Furthermore, a plurality of ventilation apertures 126 may be located in the cover 124 to provide adequate heat dissipation for the digital photo album A. Naturally, the ventilation apertures 126 are located and grouped in such a manner so as to optimize the convective heat transfer from the photo album A to the surrounding environment. The ventilation apertures 126 could also take the form of multiple slits, parallel grooves or the like.

As shown in FIGS. 2 and 3 defined in the rear face 116 of the frame 112 is a cable channel 130, which is in communication with the socket 118 from a side or peripheral edge of the frame 112. The cable channel 130 provides a relief for an associated electrical cable G of the digital photo album A. The electrical cable G may serve any number of purposes. For example, the electrical cable G may provide Internet or LAN access, AC or DC power, or auxiliary audio/video input/output. At least one distinct advantage of the cable channel 130 in the frame 112 is that it provides a strain relief for the cable G such that the wires within the cable do not become fatigued adjacent to the housing B of the digital photo album A. In this manner, the cable channel 130 helps reduce wire fatigue and prolong the usable life of the digital photo album A.

As shown in FIGS. 2 and 3, the display 110 further includes a support leg or easel 132. The support leg 132 may be hingedly attached, as at 133, to the cover 124. Of course, the support leg 132 may be attached to any portion along the rear face 116 of the frame 112. As with the cover 124, the support leg 132 also includes an open position and a closed position. When the support leg 132 is in the open position and the cover 124 is in the closed position, the display 110 may be supported along a horizontal surface. To optimize or adjust the viewing angle, the support leg 132 is made to a specific length such that the front face 114 is angled slightly when the support leg 132 is in the open position and supporting the display 110. In one embodiment, not shown, the support leg can be adjustable in length so that the frame 112 can be pivoted to satisfy a given user's preference. When the support leg 132 is in the closed position, the frame 112 may be mounted conveniently along a vertical surface, such as a wall. To this end, one embodiment of the display would have suitable structures (not shown) to mount the display on a wall, or the like.

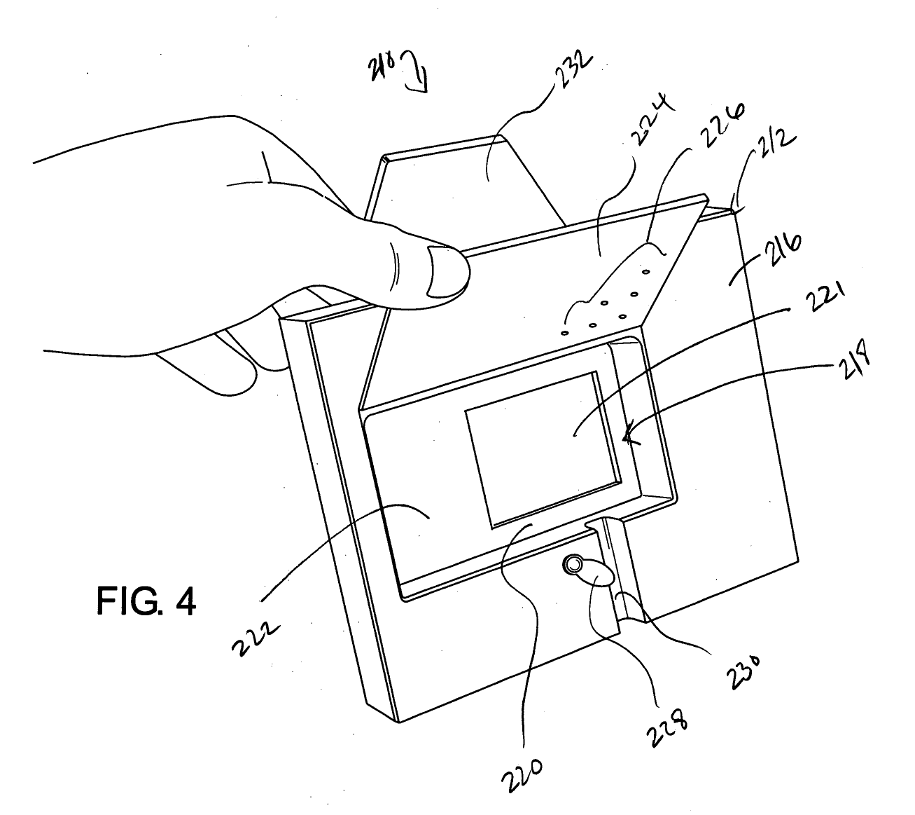

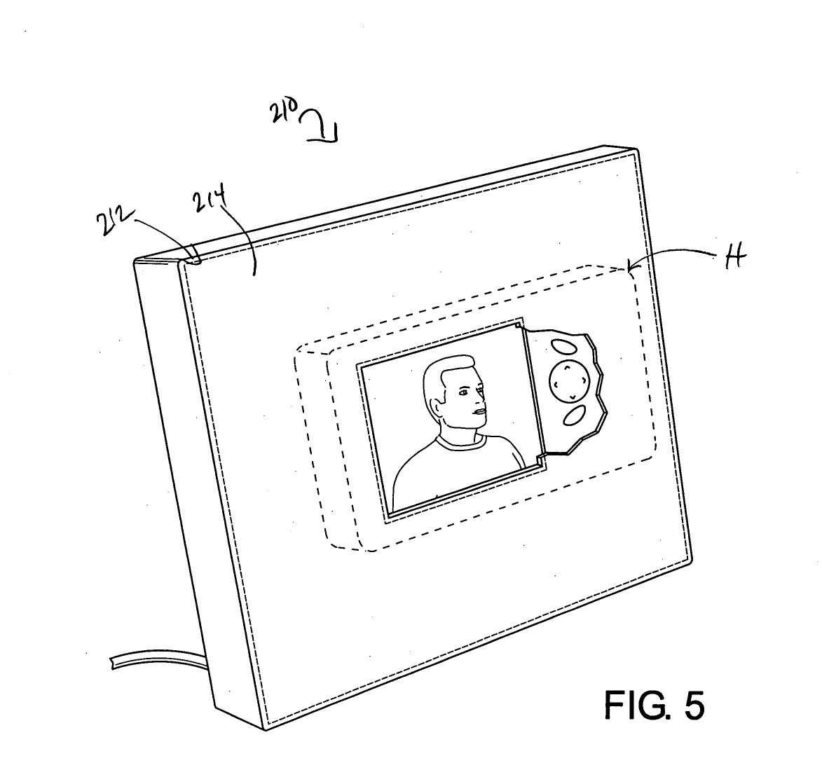

Now, with reference to FIGS. 4 and 5, a second embodiment of a digital photo album display 210 is shown. As with the first display embodiment, the display 210 includes a frame 212, having a front face 214, and a rear face 216. In addition, a socket 218 is defined within the frame 212 for receiving an associated compact digital photo album H, as shown in FIGS. 5 and 6. In order to accommodate the compact digital photo album H, the socket 218 of the second embodiment is smaller than that of the socket 118 of the first embodiment. Again, as with the first embodiment, the second embodiment includes a lip portion 220 as well as an enlarged lip section 222. The lip portion 220 serves to restrain the digital photo album H from falling out of the frame 212 in a forward direction beyond the front face 214 of the frame 212. Furthermore, the display 210 includes a cover portion 224 having a plurality of vents 226. Although the vents 226 are shown concentrated in one corner of the cover 224, it should be understood that the vents may be placed anywhere along the cover portion 224. Also the vents may take the form of slots or any other geometric shape that would optimize conductive or convective heat transfer from within the socket area 218.

The display 210 of the second embodiment also differs in that it only includes a single clasp 228 as opposed to multiple clasps. This is largely due to the fact the compact digital photo album H requires a smaller cover which requires less clasps to secure it in a closed position. Of course, any suitable number of clasps or similar fastening means could be employed. As with the first embodiment, the display 210 also serves to protect and conceal the digital photo album H, for the reasons outlined previously with respect to the first embodiment. Lastly a cable channel 230 is provided, which communicates between a peripheral edge of the frame 212 and the socket portion 218. As before, the display 210 also includes a support leg 232 for supporting the frame 212 when the cover portion 224 is in the closed position and the support leg 232 is in an open position.

There are numerous advantages to the display of the present invention. First, by enclosing the digital photo album within the socket, a protective barrier is formed about the digital photo album. The frame, the lip, the enlarged lip section, and the cover all cooperate to protect the various portions and sensitive electronics of the digital photo album. For example, the enlarged lip section prevents children and other individuals from accidentally depressing the user controls, which if done repeatedly, could either damage the digital photo album or put the various display settings in a non-preferred mode. Furthermore, the cover and the frame protect the sides and rear portions of the digital photo album. In the event that the display is dropped, the frame and cover provide an impact resistant and energy absorbing barrier between the impact surface and the digital photo album.

In addition, the display of the present invention not only aids in protecting certain portions of the associated digital photo album but it also acts to conceal the very fact that a digital photo album is held within the display. When the digital photo album is displaying still images, it is not readily apparent to the casual observer that display of the present invention is different from a standard picture frame. This stealthy appearance not only appeals to those who prefer the look of a more traditional or simple picture frame, but also to those who are concerned about theft. Because the display has an external appearance that is substantially that of a standard picture frame, a would-be thief would not be as inclined to steal the display and digital photo album. This is simply due to the fact that a thief would not immediately realize that an expensive piece of electronic equipment is actually concealed within the display of the present invention.

It should also be noted that that the frame of the first or second embodiments may be constructed from a single piece as, for example, a plastic molding, a solid wood carving, or a piece of machined metal. In addition, the frame may be constructed from a plurality of frame elements such that each element is joined end to end to construct a generally rectangular frame assembly. This may be accomplished by mitering the ends of the individual frame elements and gluing or fastening the ends together. Alternatively, a series of thin sheets may be laminated together to form the frame. Lastly, the viewing window may include a protective translucent sheet for protecting the screen from dust, UV exposure, or finger oils. Conversely, the viewing window may be left open to provide for increased circulation of air into the socket for cooling of the digital photo album device.

Modifications and alterations will occur to others upon reading and understanding the preceding detailed description. It is intended that the embodiments described herein be construed as including all such modifications and alterations, insofar as they come within the scope of the appended claims or the equivalents thereof.

1. A display for an associated digital photo album, the display comprising:
a frame member including a front face and a rear face;
a socket located in the frame member for removably receiving the associated digital photo album;
a retaining lip disposed about the socket of the frame member, the retaining lip restricting movement of the associated digital photo album beyond the front face of the frame member;
a cover moveably mounted to the rear face of the frame member for retaining the associated digital photo album in the frame member; and
wherein the frame member and the cover substantially enclose the associated digital photo album, except for a screen thereof, when the cover is in a closed position.

2. The display of claim 1, wherein the cover includes a plurality of ventilation apertures extending through the cover.

3. The display of claim 1, further including at least one clasp selectively engageable with the cover for securing the cover in the closed position, the clasp rotatably secured to the frame member.

4. The display of claim 1, further including a support leg attached to the frame member, the support leg including a closed position and an open position, the support leg stabilizing the frame member along an associated horizontal surface when the support leg is in the open position.

5. The display of claim 1, further including a cable channel disposed in the frame member for receiving an electrical cable for the associated digital photo album, the cable channel being in communication with the socket.

6. The display of claim 1, wherein at least a portion of the retaining lip conceals a portion of a front wall of the associated digital photo album.

7. The display of claim 1, wherein a portion of the retaining lip conceals at least one user control of the associated digital photo album.

8. The display of claim 1, wherein at least one of the retaining lip, the frame member, and the cover conceal a plurality of user controls of the associated digital photo album.

9. A display for an associated digital photo album, the display comprising:
a plurality of frame elements arranged to form a generally rectangular assembly, the assembly including a front face and a rear face.
a socket portion defined by the plurality of frame elements for selectively receiving the associated digital photo album, the socket portion initiating at the rear face of the assembly and extending towards the front face thereof;
a viewing window defined in the front face of the assembly, the window being in communication with the socket portion;
a cover secured to the rear face of the assembly for retaining the associated digital photo album, the cover having an open position and a closed position;
a support leg secured to the cover, the support leg including a closed position and an open position,
wherein the plurality of frame elements, the cover, and the support leg support the associated digital photo album on an associated horizontal surface when the cover member is in the closed position and the support leg is in the open position.

10. The display of claim 9, further including a cable channel disposed in the frame member for receiving an electrical cable for the associated digital photo album, the channel being in communication with the socket portion.

11. The display of claim 9, further including a retaining member selectively engageable with the cover for securing the cover in the closed position, the retaining member secured to one of the plurality of frame elements.

12. The display of claim 9, wherein the cover includes a plurality of ventilation apertures.

13. The display of claim 9, wherein a lip of the assembly is defined between the viewing window and the socket portion.

14. The display of claim 13, wherein the lip of the assembly conceals at least one user control of the associated digital photo album.

15. The display of claim 13, wherein the lip of the assembly conceals a plurality of user controls of the associated digital photo album.

16. A display for selectively supporting an associated digital photo album, the display comprising:
a frame member including a front face and a rear face;
a socket defined in the frame member and extending therethrough from said rear face to said front face thereof;
a lip defined on said frame member front face so that a front opening of said frame member has a smaller area than a rear opening of said frame member;
a cover moveably mounted to said frame member rear face and selectively closing said rear opening thereof; and
wherein the frame member and the cover cooperate to substantially enclose the associated digital photo album, except for a screen thereof.

17. The display of claim 16, wherein the cover includes a plurality of ventilation apertures extending through the cover.

18. The display of claim 16, further including at least one clasp selectively engageable with the cover for securing the cover in a closed position, the clasp being secured to the frame member.

19. The display of claim 16, further including a support leg attached to the frame member, the support leg including a closed position and an open position, the support leg stabilizing the frame member on an associated horizontal surface when the support leg is in the open position.

20. The display of claim 16, further including a cable channel disposed in the frame member for receiving an electrical cable for the associated digital photo album, the channel being in communication with the socket.
